(19) United States
(12) Patent Application Publication
(10) Pub. No.: US 2026/0046531 A1
(43) Pub. Date: Feb. 12, 2026

(54) LIGHT DETECTION ELEMENT

(71) Applicant: SONY SEMICONDUCTOR SOLUTIONS CORPORATION, KANAGAWA (JP)

(72) Inventor: Tohru TAKEDA, KANAGAWA (JP)

(21) Appl. No.: 19/104,265

(22) PCT Filed: Jul. 21, 2023
(86) PCT No.: PCT/JP2023/026854

§ 371 Date: Feb. 17, 2025

(30) Foreign Application Priority Data
Aug. 23, 2022 (JP) 2022-132733

(51) Int. Cl. H04N 25/47; G01J 1/44

(52) U.S. Cl. CPC H04N 25/47; G01J 1/44; G01J 2001/446

(57) ABSTRACT

Response characteristics are switched.

A light detection element includes: a photodiode that photoelectrically converts incident light to generate a photocurrent; a first conversion transistor that converts the photocurrent into a voltage signal and outputs the voltage signal from a gate; a current source transistor that supplies a predetermined constant current to an output signal line connected to the gate of the first conversion transistor; a voltage supply transistor that supplies a constant voltage according to the predetermined constant current from the output signal line to a source of the first conversion transistor; one or more second conversion transistors connected in parallel to the first conversion transistor and capable of converting the photocurrent into the voltage signal and outputting the voltage signal from a gate, and a connection switching section that switches a number of parallel outputs by switching an electrical connection state of the second conversion transistor, the number of parallel outputs being a number of the second conversion transistors that are connected in parallel to the first conversion transistor and convert the photocurrent into the voltage signal and output the voltage signal from the gate.

### TECHNICAL FIELD

Embodiments according to the present disclosure relate to a light detection element.

### BACKGROUND ART

There is known an imaging device that, only when some event occurs in an imaging scene, acquires data of a portion in which a brightness level has changed due to the event. This type of imaging device is sometimes referred to as an event base vision sensor (EVS) (see Patent Document 1).

Furthermore, in the imaging device, a voltage signal corresponding to the illuminance of a subject is generated according to the circuit response characteristics of a pixel.

### CITATION LIST

### Patent Document

Patent Document 1: WO 2019/087472 A

### SUMMARY OF THE INVENTION

### Problems to be Solved by the Invention

However, it is difficult to switch the response characteristics of the pixel.

Therefore, the present disclosure provides a light detection element capable of switching response characteristics.

### Solutions to Problems

In order to solve the above problem, according to the present disclosure, provided is a light detection element including:
a photodiode that photoelectrically converts incident light to generate a photocurrent;
a first conversion transistor that converts the photocurrent into a voltage signal and outputs the voltage signal from a gate;
a current source transistor that supplies a predetermined constant current to an output signal line connected to the gate of the first conversion transistor;
a voltage supply transistor that supplies a constant voltage according to the predetermined constant current from the output signal line to a source of the first conversion transistor;
one or more second conversion transistors connected in parallel to the first conversion transistor and capable of converting the photocurrent into the voltage signal and outputting the voltage signal from a gate, and
a connection switching section that switches a number of parallel outputs by switching an electrical connection state of the second conversion transistor, the number of parallel outputs being a number of the second conversion transistors that are connected in parallel to the first conversion transistor and convert the photocurrent into the voltage signal and output the voltage signal from the gate.

The connection switching section may switch the number of parallel outputs according to information regarding a state of a subject or around the subject.

The connection switching section may switch the number of parallel outputs according to illuminance of the subject or around the subject.

The connection switching section may switch the number of parallel outputs according to the voltage signal.

An event detection section that detects a change in the voltage signal as an event may be further included, and
the connection switching section may switch the number of parallel outputs according to a number of detected events.

Each of the second conversion transistors may be connected between a first node and a second node,
the first node may include a node between the photodiode and the first conversion transistor,
the second node may include a node between a first reference voltage node and the first conversion transistor, and
the connection switching section may include a first switching transistor connected between the first node and the second conversion transistor or between the second node and the second conversion transistor.

The connection switching section may include a voltage node capable of changing a voltage,
each of the second conversion transistors may be connected between the voltage node and a first node, and
the first node may include a node between the photodiode and the first conversion transistor.

The connection switching section may include a second switching transistor connected between a gate of each of the second conversion transistors and the output signal line.

The connection switching section may further include a third switching transistor connected between a third node and a second reference voltage node, and
the third node may include a node between a gate of each of the second conversion transistors and the second switching transistor.

The connection switching section may further include an inverter connected between a gate of each of the second switching transistors and a gate of the third switching transistor.

The first conversion transistor and each of the second conversion transistors may be disposed adjacent to each other.

Each of the second conversion transistors and the connection switching section may be provided in some pixels.

Each of the second conversion transistors and the connection switching section may be provided in all pixels.

### BRIEF DESCRIPTION OF DRAWINGS

FIG. 1 is a block diagram illustrating an example of a system configuration of an imaging system to which a technology according to the present disclosure is applied.

FIG. 2 is a block diagram illustrating an example of a configuration of an imaging device according to a first configuration example of the present disclosure.

FIG. 3 is a block diagram illustrating an example of a configuration of a pixel array section.

FIG. 4 is a circuit diagram illustrating an example of a circuit configuration of a pixel.

FIG. 5 is a block diagram illustrating a first configuration example of an address event detection section.

FIG. 6 is a circuit diagram illustrating an example of a configuration of a current-voltage conversion section in the address event detection section.

FIG. 7 is a circuit diagram illustrating an example of configurations of a subtractor and a quantizer in the address event detection section.

FIG. 8 is a block diagram illustrating a second configuration example of the address event detection section.

FIG. 9 is a block diagram illustrating an example of a configuration of an imaging device according to a second configuration example of the present disclosure.

FIG. 10 is an exploded perspective view schematically illustrating a stacked chip structure of the imaging device.

FIG. 11 is a block diagram illustrating an example of a configuration of a column processing section of the imaging device according to the first configuration example.

FIG. 12 is a circuit diagram illustrating an example of a configuration of a pixel according to a first embodiment.

FIG. 13 is a layout diagram illustrating an example of a configuration of the pixel according to the first embodiment.

FIG. 14 is a diagram illustrating an example of response characteristics of the pixel according to the first embodiment.

FIG. 15 is a circuit diagram illustrating an example of a configuration of a pixel according to a comparative example.

FIG. 16 is a diagram illustrating an example of response characteristics of the pixel according to the comparative example.

FIG. 17 is a circuit diagram illustrating an example of a configuration of a pixel according to a second embodiment.

FIG. 18 is a circuit diagram illustrating an example of a configuration of a pixel according to a third embodiment.

FIG. 19 is a circuit diagram illustrating an example of a configuration of a pixel according to a fourth embodiment.

FIG. 20 is a circuit diagram illustrating an example of a configuration of a pixel according to a fifth embodiment.

FIG. 21 is a circuit diagram illustrating an example of a configuration of a pixel according to a sixth embodiment.

FIG. 22 is a circuit diagram illustrating an example of a configuration of a pixel according to a seventh embodiment.

FIG. 23 is a diagram illustrating an example of response characteristics of a pixel according to an eighth embodiment.

FIG. 24 is a schematic diagram representing an overall configuration example of an electronic device.

FIG. 25 is a block diagram illustrating an example of a schematic configuration of a vehicle control system.

FIG. 26 is an explanatory diagram illustrating an example of installation positions of an outside-vehicle information detecting section and an imaging section.

### MODE FOR CARRYING OUT THE INVENTION

Hereinafter, embodiments of a light detection element will be described with reference to the drawings. In the following, main configuration parts of the light detection element will be described, but the light detection element may have configuration parts and functions that are not illustrated or described. The following description is not intended to exclude configuration parts and functions that are not illustrated or described.

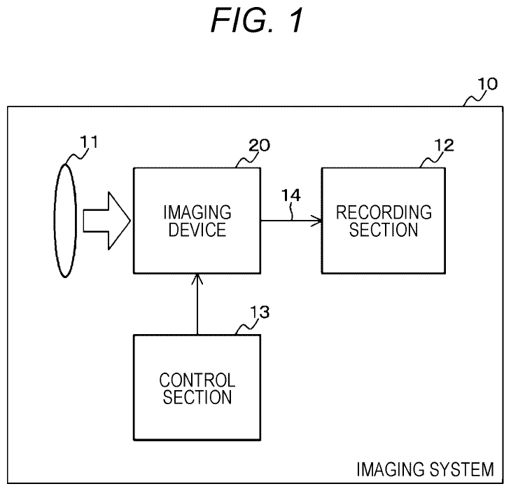

FIG. 1 is a block diagram illustrating an example of a system configuration of an imaging system to which a technology according to the present disclosure is applied.

As illustrated in FIG. 1, an imaging system 10 to which the technology according to the present disclosure is applied includes an imaging lens 11, an imaging device 20, a recording section 12, and a control section 13. The imaging system 10 is an example of an electronic device of the present disclosure, and examples of the electronic device include a camera system mounted on an industrial robot, a vehicle-mounted camera system, and the like.

In the imaging system 10 having the above configuration, the imaging lens 11 captures incident light from a subject and forms an image on an imaging surface of the imaging device 20. The imaging device 20 photoelectrically converts the incident light captured by the imaging lens 11 in units of pixels to acquire imaging data. As the imaging device 20, an imaging device (a light detection element) of the present disclosure described later is used.

The imaging device 20 performs predetermined signal processing such as image recognition processing on captured image data, and outputs data indicating a processing result and a detection signal (Hereinafter, it may be simply described as a “detection signal”.) of an address event to be described later to the recording section 12. A generation method of the detection signal of the address event will be described later. The recording section 12 stores data supplied from the imaging device 20 via a signal line 14. The control section 13 includes, for example, a microcomputer, and controls an imaging operation in the imaging device 20.

### Imaging Device According to First Configuration Example (Arbiter Method)

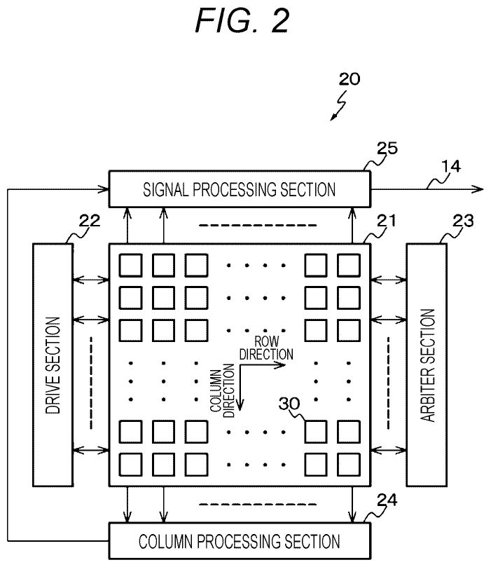

FIG. 2 is a block diagram illustrating an example of a configuration of an imaging device according to a first configuration example used as the imaging device 20 in the imaging system 10 to which the technology according to the present disclosure is applied.

As illustrated in FIG. 2, the imaging device 20 according to the first configuration example as the imaging device of the present disclosure is an asynchronous imaging device called EVS, and includes a pixel array section 21, a drive section 22, an arbiter section (arbitration section) 23, a column processing section 24, and a signal processing section 25.

In the imaging device 20 having the above configuration, a plurality of pixels 30 is two-dimensionally arranged in a matrix (array) in the pixel array section 21. A vertical signal line VSL to be described later is wired for each pixel column with respect to this matrix-like pixel array.

Each of the plurality of pixels 30 generates an analog signal of a voltage corresponding to a photocurrent as a pixel signal. Furthermore, each of the plurality of pixels 30 detects the presence or absence of an address event depending on whether or not a change amount of the photocurrent exceeds a predetermined threshold value. Then, when the address event occurs, the pixel 30 outputs a request to the arbiter section 23.

The drive section 22 drives each of the plurality of pixels 30 to output a pixel signal generated in each pixel 30 to the column processing section 24.

The arbiter section 23 arbitrates a request from each of the plurality of pixels 30 and transmits a response based on an arbitration result to the pixel 30. The pixel 30 that has received the response from the arbiter section 23 supplies a detection signal (detection signal of the address event) indicating a detection result to the drive section 22 and the signal processing section 25. The reading of the detection signal from the pixel 30 can be performed by reading a plurality of rows.

The column processing section 24 includes, for example, an analog-to-digital converter, and performs processing of converting an analog pixel signal output from the pixel 30 of the column into a digital signal for each pixel column of the pixel array section 21. Then, the column processing section 24 supplies the analog-digital converted digital signal to the signal processing section 25.

The signal processing section 25 performs predetermined signal processing such as correlated double sampling (CDS) processing or image recognition processing on the digital signal supplied from the column processing section 24. Then, the signal processing section 25 supplies the data indicating a processing result and the detection signal supplied from the arbiter section 23 to the recording section 12 (see FIG. 1) via the signal line 14.

### Configuration Example of Pixel Array Section

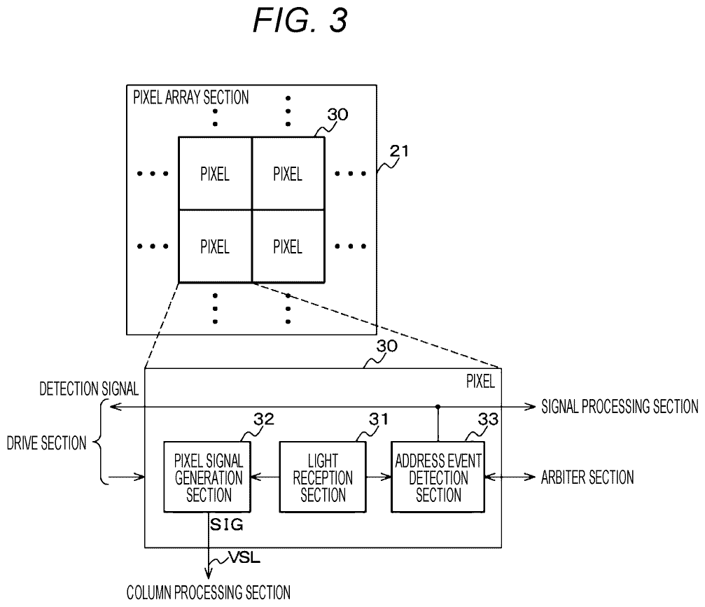

FIG. 3 is a block diagram illustrating an example of a configuration of the pixel array section 21.

In the pixel array section 21 in which the plurality of pixels 30 is two-dimensionally arranged in a matrix, each of the plurality of pixels 30 includes a light reception section 31, a pixel signal generation section 32, and an address event detection section 33.

In the pixel 30 having the above configuration, the light reception section 31 photoelectrically converts incident light to generate a photocurrent. Then, the light reception section 31 supplies the photocurrent generated by photoelectric conversion to either the pixel signal generation section 32 or the address event detection section 33 under the control of the drive section 22 (see FIG. 2).

The pixel signal generation section 32 generates a signal of a voltage according to the photocurrent supplied from the light reception section 31 as a pixel signal SIG, and supplies the generated pixel signal SIG to the column processing section 24 (see FIG. 2) via the vertical signal line VSL.

The address event detection section 33 detects the presence or absence of an address event depending on whether or not a change amount of the photocurrent from each of the light reception sections 31 exceeds a predetermined threshold value. The address event includes, for example, an on-event indicating that the change amount of the photocurrent exceeds an upper limit threshold value and an off-event indicating that the change amount falls below a lower limit threshold value. Furthermore, the detection signal of the address event includes, for example, one bit indicating the detection result of the on-event and one bit indicating the detection result of the off-event. Note that the address event detection section 33 can be configured to detect only an on-event.

When an address event occurs, the address event detection section 33 supplies a request for requesting transmission of the detection signal of the address event to the arbiter section 23 (see FIG. 2). Then, upon receiving a response to the request from the arbiter section 23, the address event detection section 33 supplies the detection signal of the address event to the drive section 22 and the signal processing section 25.

### Example of Circuit Configuration of Pixel

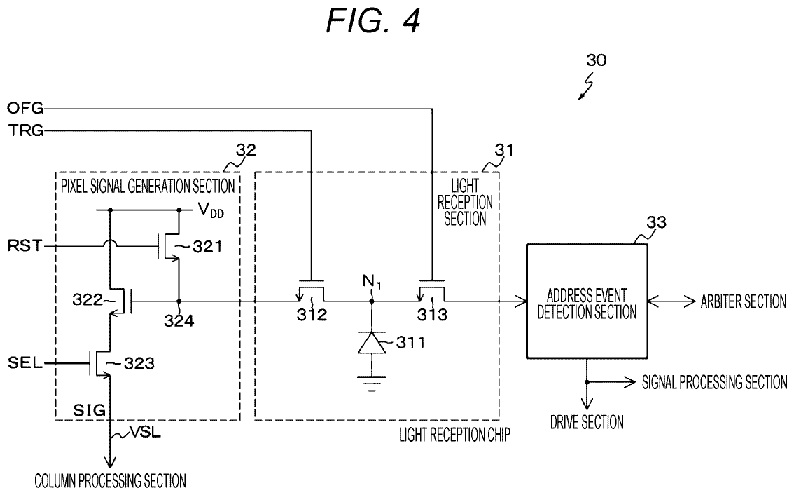

FIG. 4 is a circuit diagram illustrating an example of a circuit configuration of the pixel 30. As described above, each of the plurality of pixels 30 includes the light reception section 31, the pixel signal generation section 32, and the address event detection section 33.

In the pixel 30 having the above configuration, the light reception section 31 includes a light reception element (photoelectric conversion element) 311, a transfer transistor 312, and an over flow gate (OFG) transistor 313. For example, N-type metal oxide semiconductor (MOS) transistors are used as the transfer transistor 312 and the OFG transistor 313. The transfer transistor 312 and the OFG transistor 313 are connected in series with each other.

The light reception element 311 is connected between a connection node N1 common to the transfer transistor 312 and the OFG transistor 313, and the ground, and photoelectrically converts the incident light to generate electric charges in an amount according to the amount of the incident light.

A transfer signal TRG is supplied from the drive section 22 illustrated in FIG. 2 to a gate electrode of the transfer transistor 312. The transfer transistor 312 supplies the electric charge photoelectrically converted by the light reception element 311 to the pixel signal generation section 32 in response to the transfer signal TRG.

A control signal OFG is supplied from the drive section 22 to a gate electrode of the OFG transistor 313. In response to the control signal OFG, the OFG transistor 313 supplies an electrical signal generated by the light reception element 311 to the address event detection section 33. The electrical signal supplied to the address event detection section 33 is a photocurrent including charges.

The pixel signal generation section 32 includes a reset transistor 321, an amplification transistor 322, a selection transistor 323, and a floating diffusion layer 324. For example, N-type MOS transistors are used as the reset transistor 321, the amplification transistor 322, and the selection transistor 323.

The electric charge photoelectrically converted by the light reception element 311 is supplied from the light reception section 31 to the pixel signal generation section 32 by the transfer transistor 312. The electric charge supplied from the light reception section 31 is accumulated in the floating diffusion layer 324. The floating diffusion layer 324 generates a voltage signal having a voltage value according to an amount of accumulated electric charges. That is, the floating diffusion layer 324 converts an electric charge into a voltage.

The reset transistor 321 is connected between a power supply line of a power supply voltage VDD and the floating diffusion layer 324. A reset signal RST is supplied from the drive section 22 to a gate electrode of the reset transistor 321. The reset transistor 321 initializes (resets) the amount of electric charges in the floating diffusion layer 324 in response to the reset signal RST.

The amplification transistor 322 is connected in series with the selection transistor 323 between the power supply line of the power supply voltage VDD and the vertical signal line VSL. The amplification transistor 322 amplifies a voltage signal subjected to charge-voltage conversion by the floating diffusion layer 324.

A selection signal SEL is supplied from the drive section 22 to a gate electrode of the selection transistor 323. In response to the selection signal SEL, the selection transistor 323 outputs the voltage signal amplified by the amplification transistor 322 to the column processing section 24 (see FIG. 2) via the vertical signal line VSL as the pixel signal SIG.

In the imaging device 20 including the pixel array section 21 in which the pixels 30 having the above-described configuration are two-dimensionally arranged, when an instruction to start detection of an address event is given by the control section 13 illustrated in FIG. 1, the drive section 22 supplies the control signal OFG to the OFG transistor 313 of the light reception section 31, thereby driving the OFG transistor 313 to supply a photocurrent to the address event detection section 33.

Then, when an address event is detected in a certain pixel 30, the drive section 22 turns off the OFG transistor 313 of the pixel 30 and stops the supply of the photocurrent to the address event detection section 33. Next, the drive section 22 drives the transfer transistor 312 by supplying the transfer signal TRG to the transfer transistor 312, and transfers the charge photoelectrically converted by the light reception element 311 to the floating diffusion layer 324.

In this manner, the imaging device 20 including the pixel array section 21 in which the pixels 30 having the above-described configuration are two-dimensionally arranged outputs only the pixel signal of the pixel 30 in which the address event is detected to the column processing section 24. As a result, regardless of the presence or absence of the address event, the power consumption of the imaging device 20 and the processing amount of the image processing can be reduced as compared with the case of outputting the pixel signals of all the pixels.

Note that the configuration of the pixel 30 exemplified here is an example, and is not limited to this configuration example. For example, a pixel configuration without the pixel signal generation section 32 is also possible. In the case of this pixel configuration, it is only required that the light reception section 31 does not include the OFG transistor 313 and the transfer transistor 312 is only required to have the function of the OFG transistor 313.

### First Configuration Example of Address Event Detection Section

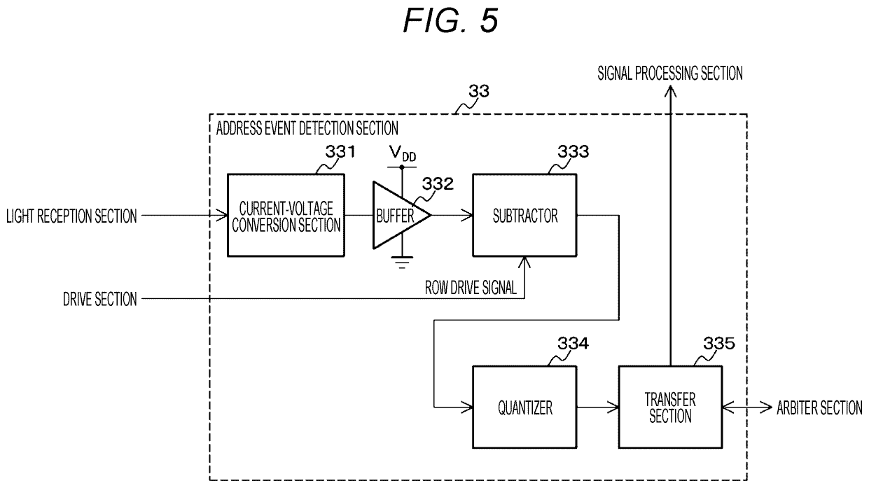

FIG. 5 is a block diagram illustrating a first configuration example of the address event detection section 33. As illustrated in FIG. 5, the address event detection section 33 according to the present configuration example includes a current-voltage conversion section 331, a buffer 332, a subtractor 333, a quantizer 334, and a transfer section 335.

The current-voltage conversion section 331 converts the photocurrent from the light reception section 31 of the pixel 30 into a logarithmic voltage signal. The current-voltage conversion section 331 supplies the converted voltage signal to the buffer 332. The buffer 332 buffers the voltage signal supplied from the current-voltage conversion section 331 and supplies the buffered voltage signal to the subtractor 333.

A row drive signal is supplied from the drive section 22 to the subtractor 333. The subtractor 333 lowers the level of the voltage signal supplied from the buffer 332 in accordance with the row drive signal. Then, the subtractor 333 supplies the voltage signal whose level has been lowered to the quantizer 334. The quantizer 334 quantizes the voltage signal supplied from the subtractor 333 into a digital signal and outputs the digital signal to the transfer section 335 as a detection signal of an address event.

The transfer section 335 transfers the detection signal of the address event supplied from the quantizer 334 to the arbiter section 23 or the like. When the address event is detected, the transfer section 335 supplies a request for requesting transmission of the detection signal of the address event to the arbiter section 23. Then, upon receiving a response to the request from the arbiter section 23, the transfer section 335 supplies the detection signal of the address event to the drive section 22 and the signal processing section 25.

Next, configuration examples of the current-voltage conversion section 331, the subtractor 333, and the quantizer 334 in the address event detection section 33 will be described.

### Configuration Example of Current-Voltage Conversion Section

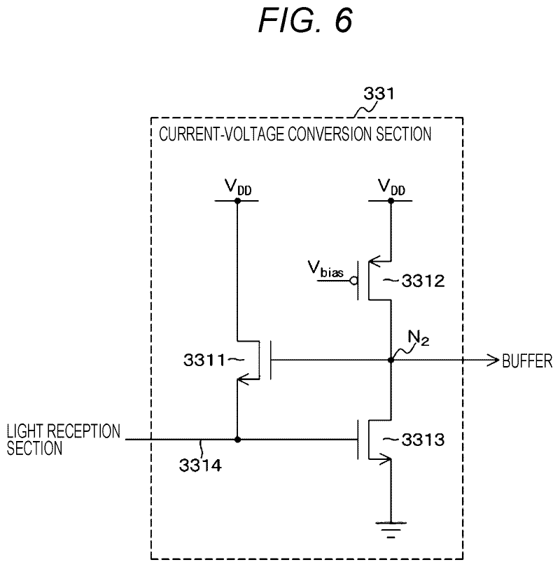

FIG. 6 is a circuit diagram illustrating an example of a configuration of the current-voltage conversion section 331 in the address event detection section 33. As illustrated in FIG. 6, the current-voltage conversion section 331 according to the present example has a circuit configuration including an N-type transistor 3311, a P-type transistor 3312, and an N-type transistor 3313. For example, MOS transistors are used as these transistors 3311 to 3313.

The N-type transistor 3311 is connected between the power supply line of the power supply voltage VDD and a signal input line 3314. The P-type transistor 3312 and the N-type transistor 3313 are connected in series between the power supply line of the power supply voltage VDD and the ground. Then, a common connection node N2 of the P-type transistor 3312 and the N-type transistor 3313 is connected to a gate electrode of the N-type transistor 3311 and an input terminal of the buffer 332 illustrated in FIG. 5.

A predetermined bias voltage Vbias is applied to a gate electrode of the P-type transistor 3312. As a result, the P-type transistor 3312 supplies a constant current to the N-type transistor 3313. A photocurrent is input from the light reception section 31 to a gate electrode of the N-type transistor 3313 through the signal input line 3314.

Drain electrodes of the N-type transistor 3311 and the N-type transistor 3313 are connected to a power supply side, and such a circuit is called a source follower. The photocurrent from the light reception section 31 is converted into a logarithmic voltage signal by the two source followers connected in a loop.

### Configuration Example of Subtractor and Quantizer

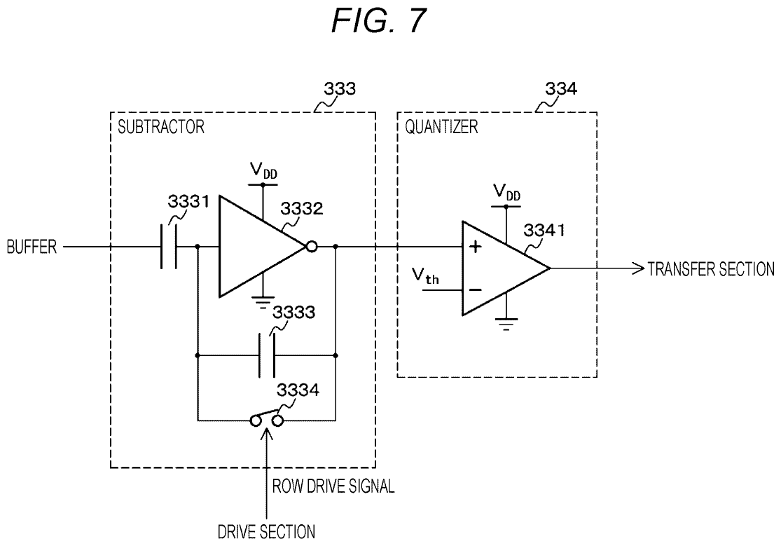

FIG. 7 is a circuit diagram illustrating an example of configurations of the subtractor 333 and the quantizer 334 in the address event detection section 33.

The subtractor 333 according to the present example includes a capacitive element 3331, an inverter circuit 3332, a capacitive element 3333, and a switch element 3334.

One end of the capacitive element 3331 is connected to an output terminal of the buffer 332 illustrated in FIG. 5, and the other end thereof is connected to an input terminal of the inverter circuit 3332. The capacitive element 3333 is connected in parallel to the inverter circuit 3332. The switch element 3334 is connected between both ends of the capacitive element 3333. A row drive signal is supplied from the drive section 22 to the switch element 3334 as an opening/closing control signal. The switch element 3334 turns on or off a path connecting both ends of the capacitive element 3333 according to the row drive signal. The inverter circuit 3332 inverts the polarity of the voltage signal input via the capacitive element 3331.

In the subtractor 333 having the above configuration, when the switch element 3334 is turned on (closed), a voltage signal Vinit is input to a terminal of the capacitive element 3331 on a buffer 332 side, and a terminal on the opposite side serves as a virtual ground terminal. A potential of the virtual ground terminal is set to zero for convenience. At this time, when a capacitance value of the capacitive element 3331 is C1, an electric charge Qinit accumulated in the capacitive element 3331 is expressed by the following Formula (1). On the other hand, since both ends of the capacitive element 3333 are short-circuited, the capacitive element 3333 has no accumulated electric charges.

$$Qinit = C 1 \times Vinit \qquad ( 1 )$$

Next, considering a case where the switch element 3334 is turned off (open) and the voltage of the terminal of the capacitive element 3331 on the buffer 332 side changes to Vafter, an electric charge Qafter accumulated in the capacitive element 3331 is expressed by the following Formula (2).

$$Qafter = C 1 \times Vafter \qquad ( 2 )$$

On the other hand, when a capacitance value of the capacitive element 3333 is C2 and an output voltage is Vout, an electric charge Q2 accumulated in the capacitive element 3333 is expressed by the following Formula (3).

$$Q 2 = - C 2 \times Vout \qquad ( 3 )$$

At this time, since the total electric charge amount of the capacitive element 3331 and the capacitive element 3333 does not change, the following Formula (4) is established.

$$Qinit = Qafter + Q 2 \qquad ( 4 )$$

When Formulas (1) to (3) are substituted into Formula (4) and rearranged, the following Formula (5) is obtained.

$$Vout = - ( C 1 / C 2 ) \times ( Vafter - Vinit ) \qquad ( 5 )$$

Formula (5) represents a subtraction operation of the voltage signal, and the gain of the subtraction result is C1/C2. Since it is generally desired to maximize the gain, it is preferable to design C1 larger and C2 smaller. On the other hand, when C2 is too small, kTC noise increases, and noise characteristics may deteriorate. Therefore, the decrease in capacitance C2 is limited to a range in which noise can be tolerated. Furthermore, since the address event detection section 33 including the subtractor 333 is mounted for each pixel 30, the capacitive element 3331 and the capacitive element 3333 have area restrictions. In consideration of these, the capacitance values C1 and C2 of the capacitive elements 3331 and 3333 are determined.

In FIG. 7, the quantizer 334 includes a comparator 3341. The comparator 3341 takes an output signal of the inverter circuit 3332, that is, a voltage signal from the subtractor 430 as a non-inverting (+) input, and takes a predetermined threshold voltage Vth as an inverting (−) input. Then, the comparator 3341 compares the voltage signal from the subtractor 430 with the predetermined threshold voltage Vth, and outputs a signal indicating a comparison result to the transfer section 335 as a detection signal of the address event.

### Second Configuration Example of Address Event Detection Section

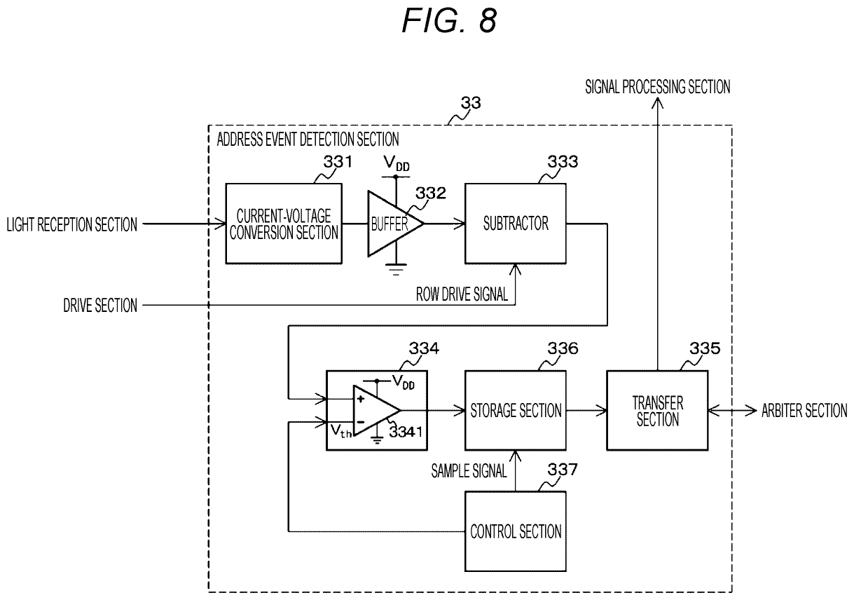

FIG. 8 is a block diagram illustrating a second configuration example of the address event detection section 33. As illustrated in FIG. 8, the address event detection section 33 according to the present configuration example includes a storage section 336 and a control section 337 in addition to the current-voltage conversion section 331, the buffer 332, the subtractor 333, the quantizer 334, and the transfer section 335.

The storage section 336 is provided between the quantizer 334 and the transfer section 335, and accumulates an output of the quantizer 334, that is, a comparison result of the comparator 3341 on the basis of a sample signal supplied from the control section 337. The storage section 336 may be a sampling circuit such as a switch, plastic, or a capacitor, or may be a digital memory circuit such as a latch or a flip-flop.

The control section 337 supplies a predetermined threshold voltage Vth to an inverting (−) input terminal of the comparator 3341. The threshold voltage Vth supplied from the control section 337 to the comparator 3341 may have different voltage values in a time division manner. For example, the control section 337 supplies a threshold voltage Vth1 corresponding to an on-event indicating that an amount of change of the photocurrent exceeds an upper limit threshold value and a threshold voltage Vth2 corresponding to an off-event indicating that the amount of change thereof falls below a lower limit threshold value at different timings, so that one comparator 3341 can detect a plurality of types of address events.

For example, the storage section 336 may accumulate the comparison result of the comparator 3341 using the threshold voltage Vth1 corresponding to the on-event during a period in which the threshold voltage Vth2 corresponding to the off-event is supplied from the control section 337 to the inverting (−) input terminal of the comparator 3341. Note that the storage section 336 may be inside the pixel 30 or may be outside the pixel 30. Furthermore, the storage section 336 is not an essential component of the address event detection section 33. That is, the storage section 336 may not be provided.

### Imaging Device (Scanning Type) According to Second Configuration Example

The imaging device 20 according to the first configuration example described above is an asynchronous imaging device that reads an event by an asynchronous reading method. However, an event reading method is not limited to the asynchronous reading method, and may be a synchronous reading method. The imaging device to which the synchronous reading method is applied is a scanning type imaging device, the same as a normal imaging device that performs imaging at a predetermined frame rate.

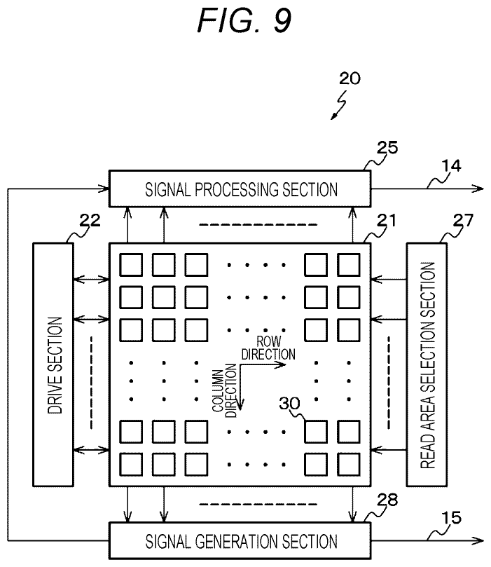

FIG. 9 is a block diagram illustrating an example of a configuration of an imaging device according to the second configuration example, that is, a scanning type imaging device used as the imaging device 20 in the imaging system 10 to which the technology according to the present disclosure is applied.

As illustrated in FIG. 9, the imaging device 20 according to the second configuration example as the imaging device of the present disclosure includes the pixel array section 21, the drive section 22, the signal processing section 25, a read area selection section 27, and a signal generation section 28.

The pixel array section 21 includes the plurality of pixels 30. The plurality of pixels 30 outputs an output signal in response to a selection signal of the read area selection section 27. Each of the plurality of pixels 30 may have a quantizer in the pixel as illustrated in FIG. 7, for example. The plurality of pixels 30 outputs an output signal corresponding to an amount of change in the intensity of light. The plurality of pixels 30 may be two-dimensionally arranged in a matrix as illustrated in FIG. 9.

The drive section 22 drives each of the plurality of pixels 30 to output a pixel signal generated in each pixel 30 to the signal processing section 25. Note that the drive section 22 and the signal processing section 25 are circuit sections for acquiring gradation information. Therefore, in a case where only the event information is acquired, the drive section 22 and the signal processing section 25 may not be provided.

The read area selection section 27 selects some of the plurality of pixels 30 included in the pixel array section 21. For example, the read area selection section 27 selects any one or a plurality of rows among the rows included in the structure of the two-dimensional matrix corresponding to the pixel array section 21. The read area selection section 27 sequentially selects one or a plurality of rows according to a preset cycle. Furthermore, the read area selection section 27 may determine the selected area according to a request from each pixel 30 of the pixel array section 21.

On the basis of an output signal of the pixel selected by the read area selection section 27, the signal generation section 28 generates an event signal corresponding to an active pixel in which the event has been detected among the selected pixels. The event is an event in which the intensity of light changes. The active pixel is a pixel in which the change amount of the intensity of light corresponding to the output signal exceeds or falls below a threshold value set in advance. For example, the signal generation section 28 compares the output signal of the pixel with a reference signal, detects an active pixel that outputs the output signal in a case where the output signal is larger or smaller than the reference signal, and generates an event signal corresponding to the active pixel.

The signal generation section 28 can include, for example, a column selection circuit that arbitrates a signal entering the signal generation section 28. Furthermore, the signal generation section 28 can be configured to output not only the information of an active pixel that has detected the event but also the information of an inactive pixel that has not detected the event.

The address information and the time stamp information (for example, (X, Y, T)) of the active pixel that has detected the event are output from the signal generation section 28 through an output line 15. However, the data output from the signal generation section 28 may be not only the address information and the time stamp information but also information in a frame format (for example, (0, 0, 1, 0, . . . )).

### Configuration Example of Chip Structure

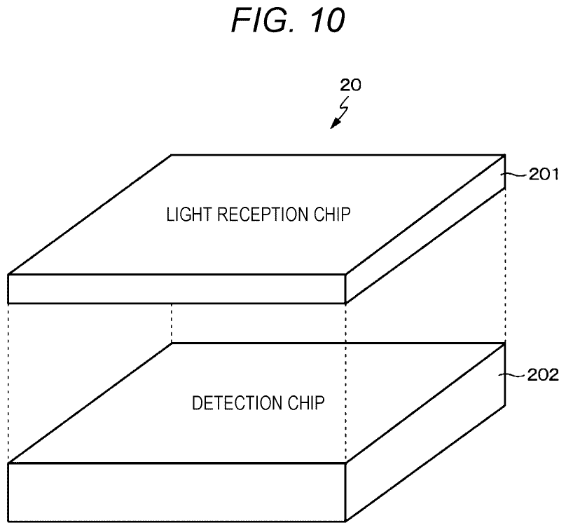

As a chip (semiconductor integrated circuit) structure of the imaging device 20 according to the first configuration example or the second configuration example described above, for example, a stacked chip structure can be adopted. FIG. 10 is an exploded perspective view schematically illustrating a stacked chip structure of the imaging device 20.

As illustrated in FIG. 10, the staked chip structure, that is, the stacked structure has a structure in which at least two chips of a light reception chip 201 that is a first chip and a detection chip 202 that is a second chip are stacked. Then, in the circuit configuration of the pixel 30 illustrated in FIG. 4, each of the light reception elements 311 is disposed on the light reception chip 201, and all elements other than the light reception element 311, elements of other circuit portions of the pixel 30, and the like are disposed on the detection chip 202. The light reception chip 201 and the detection chip 202 are electrically connected via a connection portion such as a via (VIA), Cu—Cu bonding, or a bump.

Note that, here, a configuration example in which the light reception element 311 is disposed on the light reception chip 201, and elements other than the light reception element 311, elements of other circuit portions of the pixel 30, and the like are disposed on the detection chip 202 has been exemplified, but the present disclosure is not limited to this configuration example.

For example, in the circuit configuration of the pixel 30 illustrated in FIG. 4, each element of the light reception section 31 may be disposed on the light reception chip 201, and elements other than the light reception section 31, elements of other circuit portions of the pixel 30, and the like may be disposed on the detection chip 202. Furthermore, each element of the light reception section 31, and the reset transistor 321 and the floating diffusion layer 324 of the pixel signal generation section 32 may be disposed on the light reception chip 201, and the other elements may be disposed on the detection chip 202. Moreover, a part of the elements constituting the address event detection section 33 may be disposed on the light reception chip 201 together with each element of the light reception section 31 and the like.

### Configuration Example of Column Processing Section

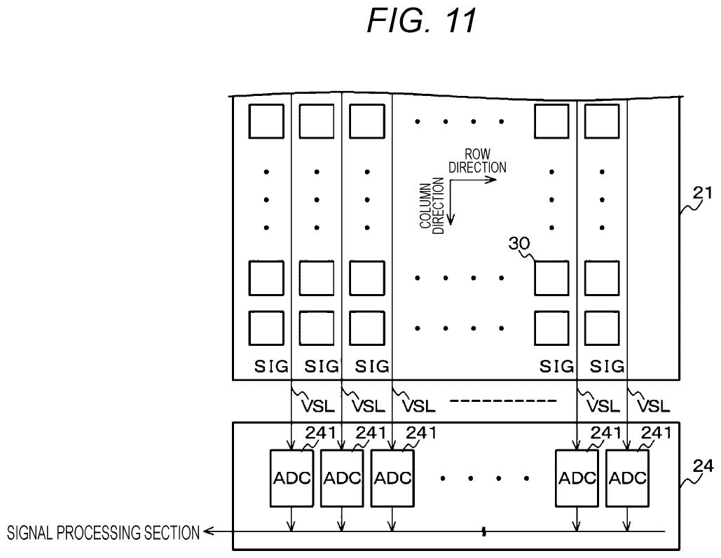

FIG. 11 is a block diagram illustrating an example of a configuration of the column processing section 24 of the imaging device 20 according to the first configuration example. As illustrated in FIG. 11, the column processing section 24 according to the present example includes a plurality of analog-digital converters (ADC) 241 arranged for each pixel column of the pixel array section 21.

Note that, here, a configuration example in which the analog-digital converter 241 is disposed in a one-to-one correspondence relationship with respect to the pixel column of the pixel array section 21 has been exemplified, but the present disclosure is not limited to this configuration example. For example, the analog-digital converter 241 may be disposed in units of a plurality of pixel columns, and the analog-digital converter 241 may be used in a time division manner between the plurality of pixel columns.

The analog-digital converter 241 converts the analog pixel signal SIG supplied via the vertical signal line VSL into a digital signal having a larger bit depth than the detection signal of the address event described above. For example, when the detection signal of the address event is 2 bits, the pixel signal is converted into a digital signal of 3 bits or more (16 bits or the like). The analog-digital converter 241 supplies the digital signal generated by the analog-digital conversion to the signal processing section 25.

### First Embodiment

### Example of Circuit Configuration of Pixel

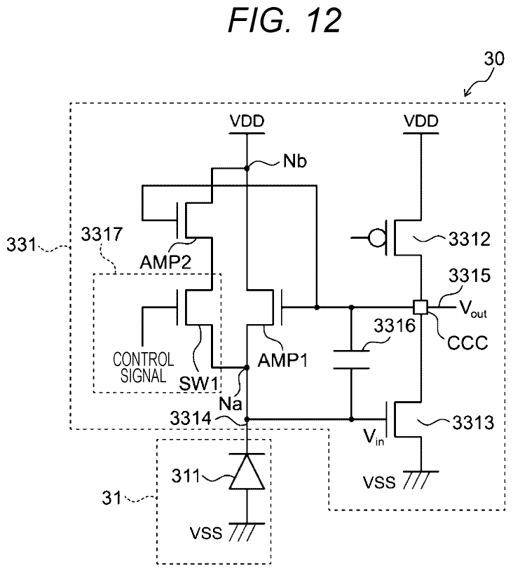

FIG. 12 is a circuit diagram illustrating an example of a configuration of a pixel 30 according to a first embodiment.

In the first embodiment, the pixel signal generation section 32, and the transfer transistor 312 and the OFG transistor 313 of the light reception section 31 illustrated in FIG. 4 are not provided. Furthermore, FIG. 12 is a diagram illustrating a light reception section 31 and a current-voltage conversion section 331.

The current-voltage conversion section 331 includes conversion transistors AMP1 and AMP2, a P-type transistor 3312, an N-type transistor 3313, a capacitor 3316, and a connection switching section 3317.

Note that the conversion transistor AMP1 illustrated in FIG. 12 corresponds to, for example, the N-type transistor 3311 illustrated in FIG. 6.

The conversion transistor (first conversion transistor) AMP1 converts a photocurrent into a voltage signal and outputs the voltage signal from a gate.

The conversion transistor (second conversion transistor) AMP2 is a transistor that is arranged in parallel with the conversion transistor AMP1 and is capable of converting a photocurrent into a voltage signal and outputting the voltage signal from a gate.

Furthermore, the conversion transistor AMP2 is connected between a node (first node) Na and a node (second node) Nb. The node Na is a node between a light reception element 311 (photodiode) and the conversion transistor AMP1. The node Nb is a node between a reference voltage node (first reference voltage node) VDD and the conversion transistor AMP1.

The P-type transistor (current source transistor) 3312 supplies a predetermined constant current to an output signal line 3315 connected to the gate of the conversion transistor AMP1.

The N-type transistor (voltage supply transistor) 3313 supplies a constant voltage according to the predetermined constant current from the output signal line 3315 to a source of the conversion transistor AMP1.

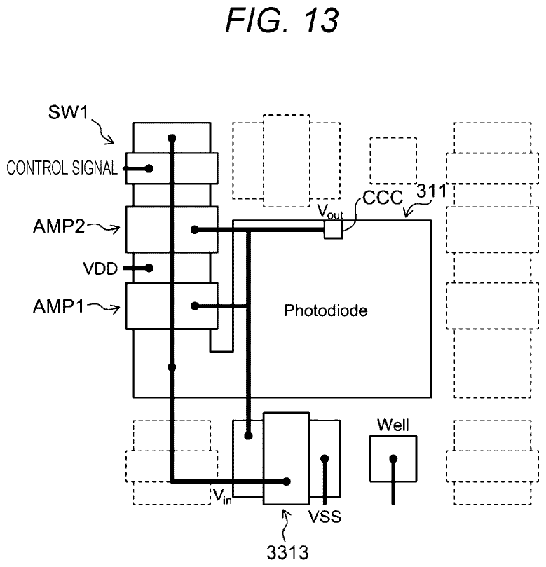

The capacitor 3316 is connected between a signal input line 3314 and the output signal line 3315. The capacitor 3316 functions as a capacitance that compensates for the phase delay of an output voltage Vout. Note that the capacitor 3316 is, for example, an interwiring capacitance described later with reference to FIG. 13.

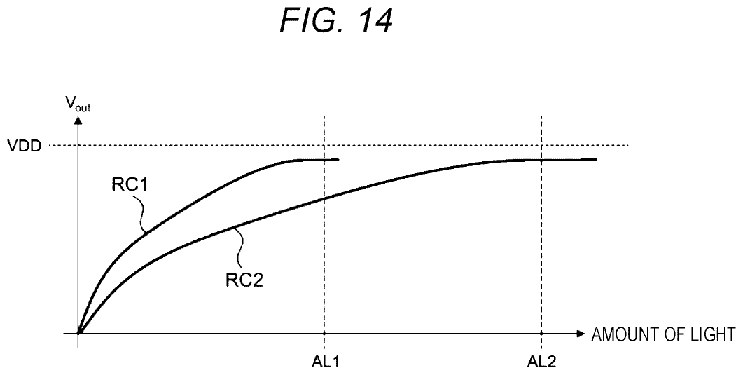

The connection switching section 3317 switches the electrical connection state of the conversion transistor AMP2 so as to change the response characteristics of the voltage signal with respect to the photocurrent. More specifically, the connection switching section 3317 switches the electrical connection state of the conversion transistor AMP2, thereby switching the number of parallel outputs which is the number of conversion transistors AMP2 that are connected in parallel with the conversion transistor AMP1, and convert an optical signal into a voltage signal and output the voltage signal from the gate. As a result, as will be described later with reference to FIG. 14, the response characteristics of the pixel 30 can be switched.

In the example illustrated in FIG. 12, the connection switching section 3317 is connected between the node Na and the conversion transistor AMP2. Furthermore, the connection switching section 3317 is connected in parallel with the conversion transistor AMP1 and connected in series with the conversion transistor AMP2.

The connection switching section 3317 includes a switching transistor (first switching transistor) SW1. A control signal is input to a gate of the switching transistor SW1. On/off of the switching transistor SW1 is controlled by the control signal. The switching transistor SW1 is, for example, an N-type transistor.

Furthermore, the light reception chip 201 and the detection chip 202 illustrated in FIG. 10 are electrically connected to each other using, for example, wiring bonding (Cu-Cu bonding) CCC. In the example illustrated in FIG. 12, the light reception section 31, the conversion transistors AMP1 and AMP2, the N-type transistor 3313, the capacitor 3316, and the connection switching section 3317 are disposed on the light reception chip 201. In the example illustrated in FIG. 12, the P-type transistor 3312 and a subsequent stage circuit subsequent to the current-voltage conversion section 331 are arranged on the detection chip 202.

FIG. 13 is a layout diagram illustrating an example of a configuration of the pixel 30 according to the first embodiment. Note that FIG. 13 illustrates a configuration of the light reception chip 100.

In the example illustrated in FIG. 13, the conversion transistor AMP1 and the conversion transistor AMP2 are disposed adjacent to each other. As a result, a difference in characteristics between the conversion transistor AMP1 and the conversion transistor AMP2 can be suppressed.

Note that the capacitor 3316 is formed, for example, between the wirings disposed in parallel.

Next, circuit response characteristics of the pixel 30 will be described.

FIG. 14 is a diagram illustrating an example of response characteristics of the pixel 30 according to the first embodiment. The vertical axis in a graph of FIG. 14 represents an output voltage Vout. The horizontal axis represents an amount of light (illuminance of a subject or the like) incident on the pixel 30. Note that the amount of light corresponds to a photocurrent generated by the light reception section 31.

FIG. 14 illustrates two response characteristics RC1 and RC2. The response characteristics RC1 are response characteristics in a case where the switching transistor SW1 is in an off state. The response characteristics RC2 are response characteristics in a case where the switching transistor SW1 is in an on state. Each of the response characteristics RC1 and RC2 indicates logarithmic response type characteristics.

In a case where the switching transistor SW1 is in the off state, the conversion transistor AMP2 is not driven. That is, the photocurrent flows through the conversion transistor AMP1 but does not flow through the conversion transistor AMP2. The conversion transistor AMP1 converts the photocurrent into an output signal Vout, and outputs the output signal Vout from the gate.

In a case where the switching transistor SW2 is in the on state, the conversion transistor AMP2 is driven. That is, the photocurrent flows through both the conversion transistors AMP1 and AMP2. In this case, both the conversion transistors AMP1 and AMP2 convert the photocurrent into a voltage signal (output voltage Vout) and output the voltage signal from the gates. As the photocurrent also flows through the conversion transistor AMP2, the response characteristics of the pixel 30 change in the same manner as the increase in a gate width of the conversion transistor AMP1.

In the response characteristics RC2, the output voltage Vout is saturated with a higher light amount than the response characteristics RC1. Note that a voltage of the output voltage Vout to be saturated is, for example, a voltage lower than a voltage VDD by a threshold voltage of the transistor 3312. The output voltage Vout in the response characteristics RC1 is saturated near a light amount AL1. The output voltage Vout in the response characteristics RC2 is saturated near a light amount AL2 larger than the light amount AL1. Therefore, in the response characteristics RC2, the sensitivity decreases as compared with the response characteristics RC1, but the dynamic range is wide.

As illustrated in FIG. 14, the characteristics of the pixel 30 can be switched by switching the flow of the photocurrent and the output of the voltage by switching on and off of the switching transistor SW1.

The control signal input to the gate of the switching transistor SW1 is, for example, an external control signal arbitrarily input by a user. For example, in a case where the illuminance of a subject or an environment around the subject is high, the user inputs a control signal for turning on the switching transistor SW1. As a result, the response characteristics RC2 having a wide dynamic range is selected. Furthermore, for example, in a case where the illuminance of the subject or around the subject is low, the user inputs a control signal for turning off the switching transistor SW1. As a result, the response characteristics RC1 with high sensitivity is selected.

As described above, according to the first embodiment, the connection switching section 3317 switches the electrical connection state of the conversion transistor AMP2, thereby switching the number of parallel outputs, which is the number of conversion transistors AMP2 that are connected in parallel with the conversion transistor AMP1, and convert an optical signal into a voltage signal and output the voltage signal from the gate. Thus, the circuit characteristics of the pixel 30 can be switched.

Note that, in the first embodiment, one conversion transistor AMP2 is provided. However, a plurality of the conversion transistors AMP2 may be provided.

Furthermore, the conversion transistor AMP2 and the connection switching section 3317 may be provided in all the pixels 30, or may be provided in some of the pixels 30. In a case where the conversion transistor AMP2 and the connection switching section 3317 are provided in some of the pixels 30, for example, a thinning drive or a region of interest (ROI) may be combined with the drive of the connection switching section 3317. By setting some of the pixels 30 to have a wide dynamic range (response characteristics RC2), sensitivity can be reduced. This enables data saving and low power consumption, and facilitates signal output. Furthermore, in the detection of an address event, for example, in a case where the address event is detected in many pixels 30 in the screen, a load is applied to the arbiter section 23, and there is a possibility that it becomes difficult to appropriately drive the arbiter section. By setting some of the pixels 30 to have a wide dynamic range (response characteristics RC2), a load on the arbiter section 23 can be suppressed.

Furthermore, the conversion transistor AMP2 and the connection switching section 3317 are not limited to the EVS having the logarithmic response type pixel 30, and may be provided in another imaging device having the logarithmic response type pixel.

### Comparative Example

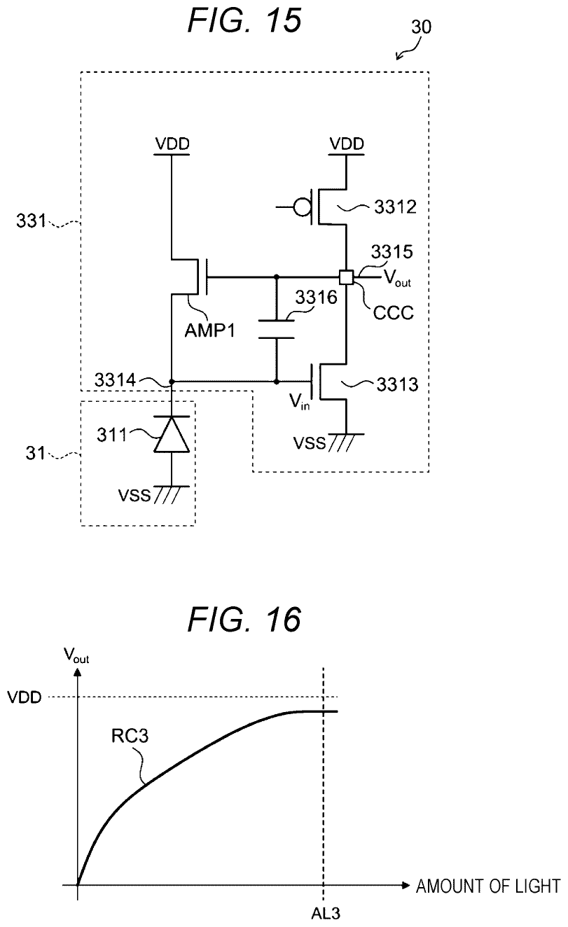

FIG. 15 is a circuit diagram illustrating an example of a configuration of a pixel 30 according to a comparative example. FIG. 16 is a diagram illustrating an example of response characteristics of the pixel 30 according to the comparative example. The comparative example is different from the first embodiment in that the conversion transistor AMP2 and the connection switching section 3317 are not provided.

In the example illustrated in FIG. 15, as illustrated in FIG. 16, the response characteristics of the pixel 30 cannot be changed.

The response characteristics RC3 illustrated in FIG. 16 are substantially the same as the response characteristics RC1 illustrated in FIG. 14 in the first embodiment. A light amount AL3 at which the output voltage Vout is substantially saturated in the response characteristics RC3 illustrated in FIG. 16 is substantially the same as the light amount AL1 at which the output voltage Vout is substantially saturated in the response characteristics RC1 illustrated in FIG. 14.

The logarithmic response type response characteristics have a wider dynamic range than the linear response type response characteristics. However, since the output voltage Vout is not higher than the voltage VDD, the output voltage Vout is saturated at a high light amount of a certain level or more, and the fluctuation of the output voltage Vout becomes small. Therefore, the higher the light amount, the more difficult it is to detect a signal change. This may lead to overlooking of a change in a high-brightness (high-illuminance) subject. Therefore, it is required to widen the dynamic range.

Furthermore, in order to widen the dynamic rending, for example, it is conceivable to change the transistor characteristics of the conversion transistor AMP1 by changing the threshold value, the gate width, the gate length, or the like of the conversion transistor AMP1. However, in this case, a problem that the sensitivity decreases in the low illuminance region occurs.

On the other hand, in the first embodiment, the response characteristics RC1 and RC2 of the pixel 30 are changed by the control signal. As a result, one pixel 30 or sensor can have a plurality of response characteristics, and supportable detection conditions or imaging conditions can be expanded. Furthermore, it is possible to selectively use (optimize) a sensitivity priority mode corresponding to the response characteristics RC1 and a dynamic range priority mode (saturation priority mode) corresponding to the response characteristics RC2 according to the situation of the subject or the environment around the subject, or the like.

### First Modification

A first modification differs from the first embodiment in a control signal input method.

The connection switching section 317 switches the number of parallel outputs according to information regarding a state of the subject or around the subject. That is, the control signal may be generated by feeding back the parameter related to the subject. As a result, the response characteristics of the pixel 30 can be automatically changed according to the state of the subject.

More specifically, the connection switching section 3317 switches the number of parallel outputs according to the voltage signals converted by the conversion transistors AMP1 and AMP2, that is, the output voltage Vout. In FIG. 14, for example, in a case where the output voltage Vout reaches a first predetermined voltage or more in the sensitivity priority mode corresponding to the response characteristics RC1, there is a possibility that the illuminance of the subject or around the subject is high. Therefore, the control signal is generated, and the connection switching section 3317 switches to the dynamic range priority mode corresponding to the response characteristics RC2. On the other hand, for example, in a case where the output voltage Vout reaches a second predetermined voltage or less in the dynamic range priority mode corresponding to the response characteristics RC2, there is a possibility that the illuminance of the subject or around the subject is low. Therefore, the control signal is generated, and the connection switching section 3317 switches to the sensitivity priority mode corresponding to the response characteristics RC1.

In a case where the pixel signal generation section 32 illustrated in FIG. 3 is not provided, the imaging device 20 includes, for example, a detection section that detects the output voltage Vout or a voltage based on the output voltage Vout.

In a case where the pixel signal generation section 32 is provided, the connection switching section 3317 may change the number of parallel outputs according to an analog signal (pixel signal) of a voltage according to the photocurrent.

As in the first modification, the input method of the control signal may be different. Also in this case, the similar effects to those of the first embodiment can be obtained.

### Second Modification

A second modification differs from the first embodiment in a control signal input method.

As described above, the comparator 3341 serving as the event detection section detects a change in the voltage signal (output voltage Vout) as an address event.

The connection switching section 3317 switches the number of parallel outputs according to the number of detected address events.

As described above, the address event includes an on-event and an off-event. The on-event is, for example, an event in which the light reception amount changes to an increase side. The off-event is, for example, an event in which the light reception amount changes to a decrease side.

The connection switching section 3317 switches the number of parallel outputs in a case where a first predetermined number of times (for example, 10 to 20 times) or more of on-events are continuously detected. In a case where the on-events are continuously detected, there is a possibility that the illuminance of the subject or around the subject is high. Therefore, the control signal is generated, and the connection switching section 3317 switches to the dynamic range priority mode. On the other hand, the connection switching section 3317 switches the number of parallel outputs in a case where the off-events are continuously detected a second predetermined number of times (for example, 10 to 20 times) or more. In a case where the off-events are detected continuously, there is a possibility that the illuminance of the subject or around the subject is low. Therefore, the control signal is generated, and the connection switching section 3317 switches to the sensitivity priority mode.

The connection switching section 3317 may change the number of parallel outputs in a case where the on-events are detected a third predetermined number of times or more than the off-events. In this case, the connection switching section 3317 switches to the dynamic range priority mode. On the other hand, the connection switching section 3317 may change the number of parallel outputs in a case where the off-events are detected a fourth predetermined number of times or more than the on-events. In this case, the connection switching section 3317 switches to the sensitivity priority mode.

As in the second modification, the input method of the control signal may be different. Also in this case, the similar effects to those of the first embodiment can be obtained.

### Third Modification

A second modification differs from the first embodiment in a control signal input method.

In a case where an electronic device such as a camera (see FIG. 24) is provided with an illuminometer that detects illuminance of a subject or around the subject, a measurement result of the illuminometer may be used to generate the control signal. That is, information necessary for generating the control signal may be input from the outside of the imaging device 20.

The connection switching section 3317 switches the number of parallel outputs according to the illuminance of the subject or around the subject.

As in the third modification, the input method of the control signal may be different. Also in this case, the similar effects to those of the first embodiment can be obtained.

### Second Embodiment

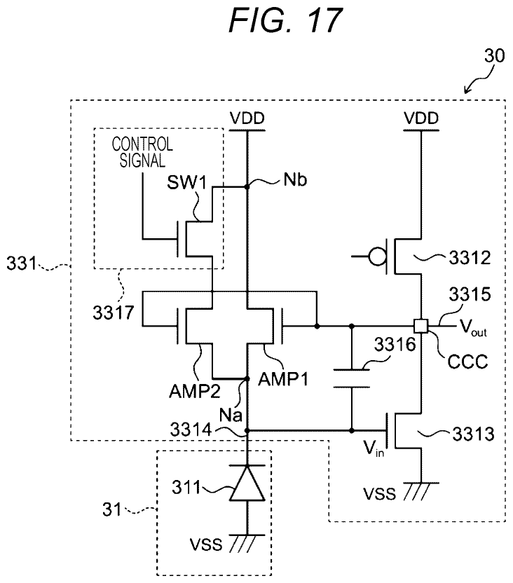

FIG. 17 is a circuit diagram illustrating an example of a configuration of a pixel 30 according to a second embodiment. The second embodiment is different from the first embodiment in that an arrangement of a conversion transistor AMP2 and a connection switching section 3317 is reversed.

The conversion transistor AMP2 is connected between the connection switching section 3317 and a node Na.

The connection switching section 3317 is connected between a node Nb and the conversion transistor AMP2.

As in the second embodiment, the arrangement of the conversion transistor AMP2 and the connection switching section 3317 may be reversed. Also in this case, the similar effects to those of the first embodiment can be obtained.

### Third Embodiment

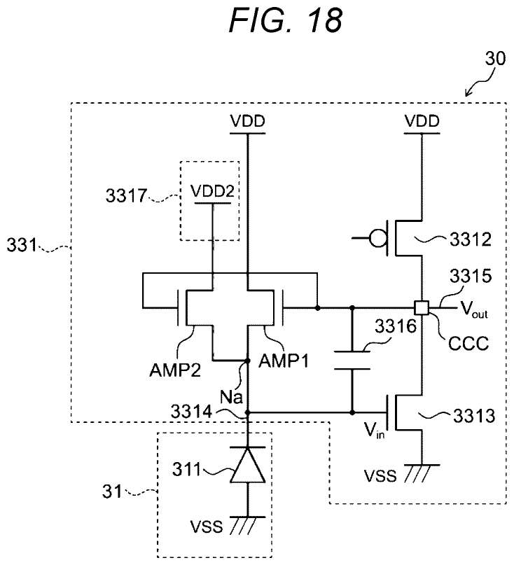

FIG. 18 is a circuit diagram illustrating an example of a configuration of a pixel 30 according to a third embodiment. The third embodiment is different from the first embodiment in a configuration of a connection switching section 3317.

The connection switching section 3317 includes a voltage node VDD2 capable of changing a voltage. The voltage of the voltage node VDD2 can be changed to, for example, a ground voltage (VSS) or a voltage VDD.

A conversion transistor AMP2 is connected between the voltage node VDD2 and a node Na. The node Na is a node between a light reception element 311 (photodiode) and a conversion transistor AMP1.

In a case where a voltage at the voltage node VDD2 is the ground voltage, the photocurrent does not flow to the conversion transistor AMP2. In this case, the pixel 30 operates with the response characteristics RC1 similarly to the case where the switching transistor SW1 illustrated in FIG. 12 is in the off state in the first embodiment.

In a case where the voltage at the voltage node VDD2 is the voltage VDD, the photocurrent flows through both the conversion transistors AMP1 and AMP2. In this case, the pixel 30 operates with the response characteristics RC2 similarly to the case where the switching transistor SW1 illustrated in FIG. 12 is in the on state in the first embodiment.

In the example illustrated in FIG. 18, the switching transistor SW1 illustrated in FIG. 12 is not provided. Therefore, the number of necessary transistors can be reduced, and the circuit area can be suppressed.

As in the third embodiment, the configuration of the connection switching section 3317 may be changed. Also in this case, the similar effects to those of the first embodiment can be obtained.

### Fourth Embodiment

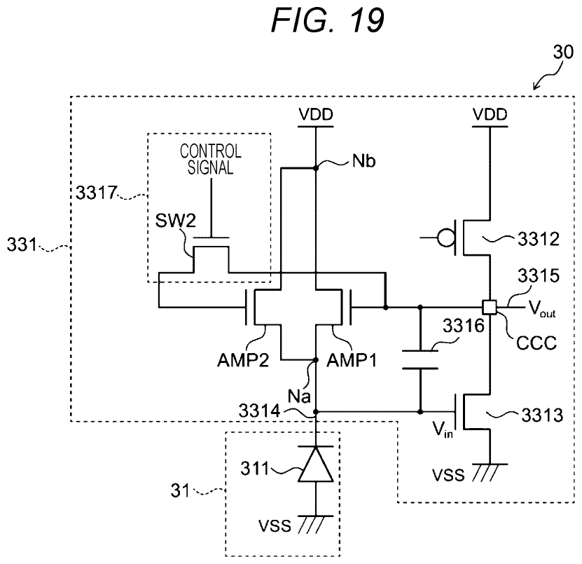

FIG. 19 is a circuit diagram illustrating an example of a configuration of a pixel 30 according to a fourth embodiment. The fourth embodiment is different from the first embodiment in a configuration of a connection switching section 3317.

The connection switching section 3317 includes a switching transistor SW2. The switching transistor (second switching transistor) SW2 is connected between a gate of a conversion transistor AMP2 and an output signal line 3315. A control signal is input to a gate of the switching transistor SW2. On/off of the switching transistor SW2 is controlled by the control signal. The switching transistor SW2 is, for example, an N-type transistor.

The control signal input to the gate of the switching transistor SW2 is substantially the same as the control signal input to the gate of the switching transistor SW1 illustrated in FIG. 12.

Furthermore, in a case where the switching transistor SW2 is in the off state, the gate capacitance visible from the output signal line 3315 can be reduced as compared with a case where the switching transistor SW1 illustrated in FIG. 12 is in the off state. Therefore, the circuit response speed can be improved.

As in the fourth embodiment, the configuration of the connection switching section 3317 may be changed. Also in this case, the similar effects to those of the first embodiment can be obtained.

### Fifth Embodiment

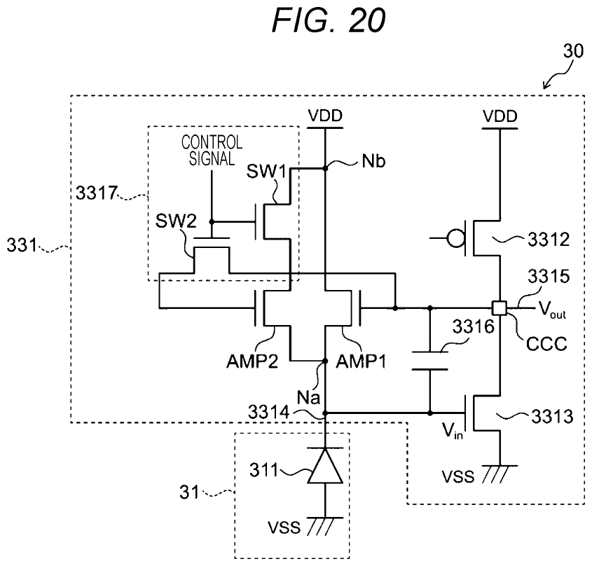

FIG. 20 is a circuit diagram illustrating an example of a configuration of a pixel 30 according to a fifth embodiment. The fifth embodiment is different from the first embodiment in a configuration of a connection switching section 3317. Note that, in the fifth embodiment, similarly to the second embodiment, an arrangement of a conversion transistor AMP2 and the connection switching section 3317 (switching transistor SW1) is reversed. Note that, the fifth embodiment is a combination of the first embodiment or the second embodiment and the fourth embodiment.

The connection switching section 3317 includes the switching transistor SW1 and a switching transistor SW2. By providing the two switching transistors SW1 and SW2, leakage characteristics can be improved. Therefore, in a case where the driving of the conversion transistor AMP2 is stopped, the driving of the conversion transistor AMP2 can be more reliably stopped.

As in the fifth embodiment, the configuration of the connection switching section 3317 may be changed. Also in this case, the similar effects to those of the first embodiment can be obtained.

### Sixth Embodiment

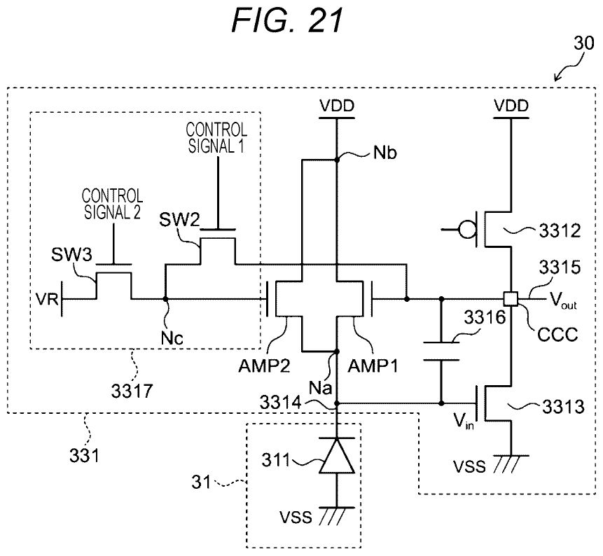

FIG. 21 is a circuit diagram illustrating an example of a configuration of a pixel 30 according to a sixth embodiment. The sixth embodiment is different from the first embodiment in a configuration of a connection switching section 3317.

The connection switching section 3317 includes switching transistors SW2 and SW3 and a reference voltage node VR.

A control signal 1 is input to a gate of the switching transistor SW2. The control signal 1 is substantially the same as the control signal input to the gate of the switching transistor SW2 illustrated in FIG. 19 in the fourth embodiment.

The switching transistor (third switching transistor) SW3 is connected between a node (third node) Nc and the reference voltage node (node of a second reference voltage) VR. The node Nc is a node between a gate of a conversion transistor AMP2 and the switching transistor SW2. A control signal 2 is input to a gate of the switching transistor SW3. The control signal 2 is, for example, a signal obtained by inverting the control signal 1. The switching transistor SW3 is, for example, an N-type transistor.

The reference voltage node VR is, for example, a ground voltage.

In FIG. 19 of the fourth embodiment, in a case where the switching transistor SW2 is in the off state, the gate of the conversion transistor AMP2 is in a floating state. Accordingly, the node Nc is electrically connected to the reference voltage node VR by turning on the switching transistor SW3 illustrated in FIG. 21. Therefore, it is possible to prevent the gate of the conversion transistor AMP2 from being in the floating state.

As in the sixth embodiment, the configuration of the connection switching section 3317 may be changed. Also in this case, the similar effects to those of the first embodiment can be obtained.

### Seventh Embodiment

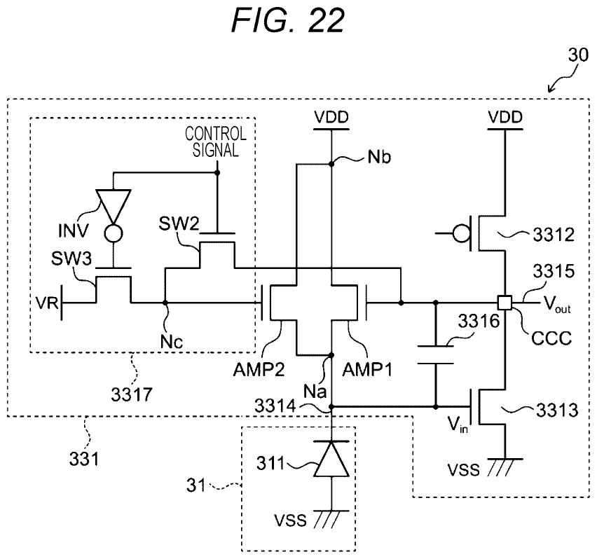

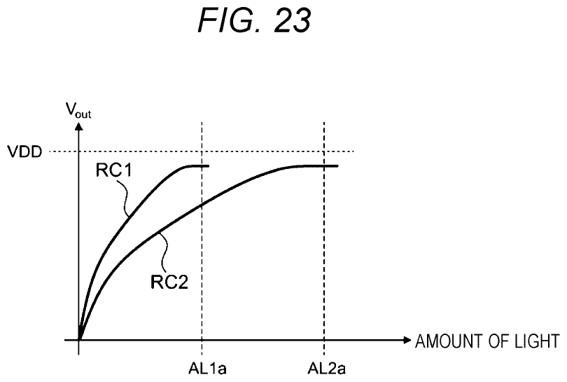

FIG. 22 is a circuit diagram illustrating an example of a configuration of a pixel 30 according to a seventh embodiment. The seventh embodiment is different from the sixth embodiment in a configuration of a connection switching section 3317.

The connection switching section 3317 further includes an inverter INV. The inverter INV is connected between a gate of a switching transistor SW2 and a gate of the switching transistor SW3. By providing the inverter INV, the number of inputs of a control signal can be reduced.

As in the seventh embodiment, the configuration of the connection switching section 3317 may be changed. In this case, effects similar to those of the sixth embodiment can be obtained.

### Eighth Embodiment

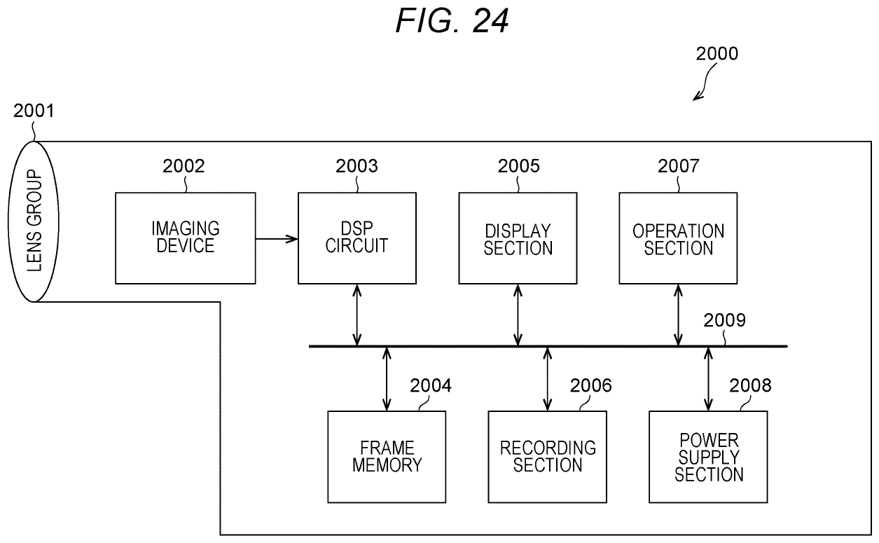

FIG. 23 is a diagram illustrating an example of response characteristics of a pixel 30 according to an eighth embodiment. The eighth embodiment is different from the first embodiment in that the transistor sizes of conversion transistors AMP1 and AMP2 are different.

In the first embodiment, as the number of conversion transistors AMP2 is increased, selectable response characteristics can be increased. However, the required area of the pixel 30 also increases.

Therefore, the required area can be decreased by reducing the transistor sizes of the conversion transistors AMP1 and AMP2.

In the eighth embodiment, the transistor size of the conversion transistor AMP1 is approximately half the transistor size of the conversion transistor AMP1 in the first embodiment. The transistor size of the conversion transistor AMP2 is approximately half the transistor size of the conversion transistor AMP1 in the first embodiment.

As the transistor sizes are changed, an amount of light with which an output voltage Vout is substantially saturated is changed.

A light amount AL2a at which the output voltage Vout is substantially saturated in response characteristics RC2 illustrated in FIG. 23 is substantially the same as the light amount AL1 at which the output voltage Vout is substantially saturated in the response characteristics RC1 illustrated in FIG. 14. Furthermore, the light amount AL2a at which the output voltage Vout is substantially saturated in the response characteristics RC2 illustrated in FIG. 23 is substantially the same as the light amount AL3 at which the output voltage Vout is substantially saturated in the response characteristics RC3 illustrated in FIG. 16 in the comparative example.

In the response characteristics RC2 illustrated in FIG. 23, a light amount AL1a at which the output voltage Vout is substantially saturated is smaller than the light amount AL2a.

In the response characteristics RC1 illustrated in FIG. 23, the dynamic range is narrower but the sensitivity is higher than that of the response characteristics RC2 illustrated in FIG. 23. In the first embodiment, the switchable response characteristics are increased to a side where the dynamic range is wide, whereas in the eighth embodiment, the switchable response characteristics can be increased to a side where the sensitivity is high. The balance between the circuit characteristics and the area efficiency can be changed by arbitrarily changing the transistor sizes.

Note that the transistor sizes may be different between the conversion transistor AMP1 and the conversion transistor AMP2.

As in the eighth embodiment, the transistor sizes of the conversion transistors AMP1 and AMP2 may be changed. Also in this case, the similar effects to those of the first embodiment can be obtained.

### Application Example to Electronic Device

FIG. 24 is a block diagram illustrating a configuration example of a camera 2000 as an electronic device to which the present technology is applied.

The camera 2000 includes an optical section 2001 including a lens group and the like, an imaging device 2002 to which the above-described imaging system 10 and the like (Hereinafter, the imaging system is referred to as imaging system 10 or the like.) are applied, and a digital signal processor (DSP) circuit 2003 which is a camera signal processing circuit. Furthermore, the camera 2000 includes a frame memory 2004, a display section 2005, a recording section 2006, an operation section 2007, and a power supply section 2008. The DSP circuit 2003, the frame memory 2004, the display section 2005, the recording section 2006, the operation section 2007, and the power supply section 2008 are connected to one another through a bus line 2009.

The optical section 2001 captures incident light (image light) from the subject and forms an image on the imaging surface of the imaging device 2002. The imaging device 2002 converts the amount of the incident light from which an image is formed on the imaging surface by the optical section 2001 into an electrical signal in units of pixels, and outputs the electrical signal as a pixel signal.

The display section 2005 is formed with a panel type display device such as a liquid crystal panel or an organic EL panel, for example, and displays a moving image or a still image captured by the imaging device 2002. The recording section 2006 records the moving image or the still image captured by the imaging device 2002 on a recording medium such as a hard disk or a semiconductor memory.

The operation section 2007 issues operation commands for various functions of the camera 2000, in response to an operation performed by a user. The power supply section 2008 supplies, as appropriate, various power sources serving as operation power sources for the DSP circuit 2003, the frame memory 2004, the display section 2005, the recording section 2006, and the operation section 2007, to these supply targets.

As described above, by using the above-described imaging system 10 or the like as the imaging device 2002, acquisition of a good image can be expected.

### Application Example to Mobile Body

The technology according to the present disclosure (the present technology) can be applied to various products. For example, the technology according to the present disclosure may be implemented in the form of a device to be mounted on a mobile body of any kind, such as an automobile, an electric vehicle, a hybrid electric vehicle, a motorcycle, a bicycle, a personal mobility, an airplane, a drone, a vessel, or a robot.

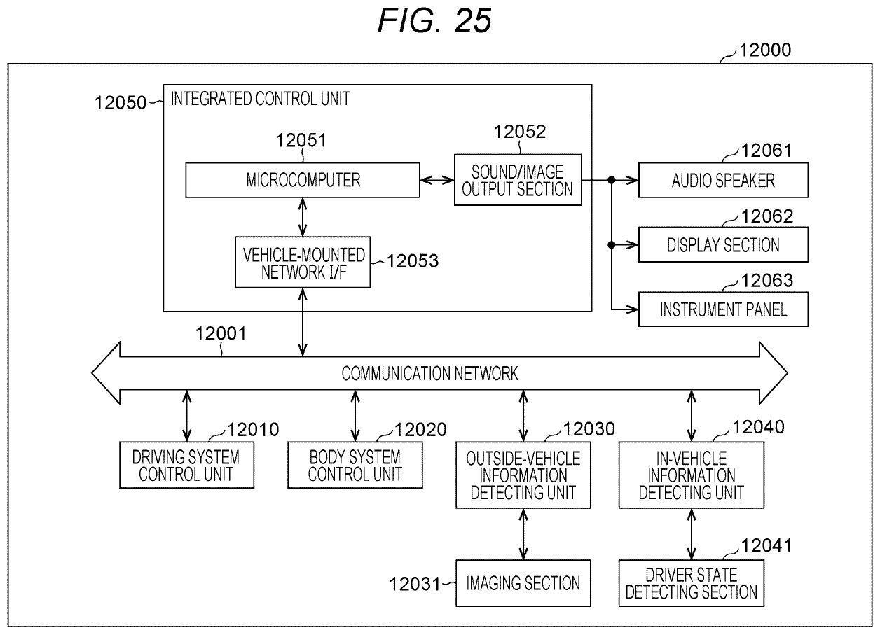

FIG. 25 is a block diagram illustrating an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example illustrated in FIG. 25, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 25, an audio speaker 12061, a display section 12062, and an instrument panel 12063 are illustrated as the output device. The display section 12062 may, for example, include at least one of an on-board display and a head-up display.

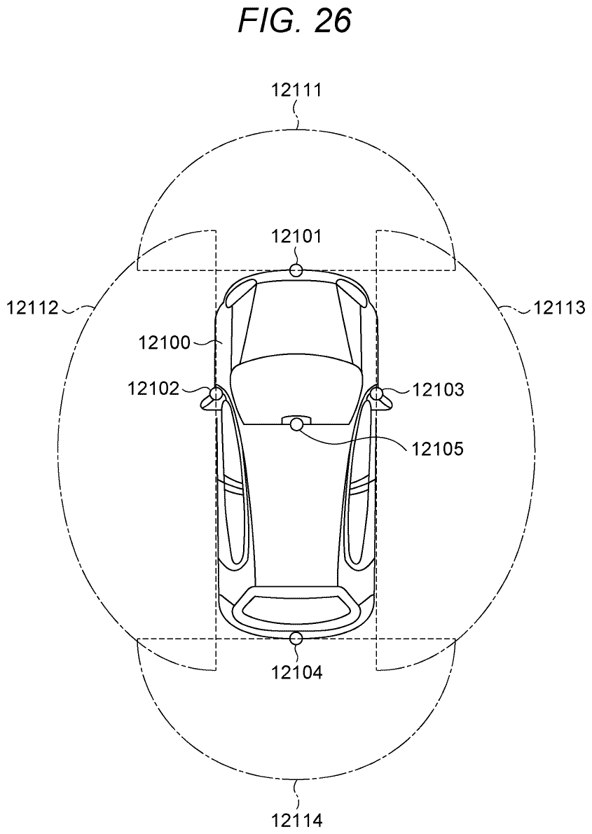

FIG. 26 is a diagram illustrating an example of an installation position of the imaging section 12031.

In FIG. 26, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 26 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to, for example, the imaging sections 12031, 12101, 12102, 12103, 12104, 12105, and the like among the above-described configurations. Specifically, for example, the imaging system 10 in FIG. 1 can be applied to these imaging sections. By applying the technology according to the present disclosure to these imaging sections, it is possible to obtain a captured image with higher sensitivity or a wider dynamic range, and thus, it is possible to perform highly accurate control using the captured image in the mobile body control system.

Note that the present technology can have the following configurations.
(1)

A light detection element including:
a photodiode that photoelectrically converts incident light to generate a photocurrent;
a first conversion transistor that converts the photocurrent into a voltage signal and outputs the voltage signal from a gate;
a current source transistor that supplies a predetermined constant current to an output signal line connected to the gate of the first conversion transistor;
a voltage supply transistor that supplies a constant voltage according to the predetermined constant current from the output signal line to a source of the first conversion transistor;
one or more second conversion transistors connected in parallel to the first conversion transistor and capable of converting the photocurrent into the voltage signal and outputting the voltage signal from a gate, and
a connection switching section that switches a number of parallel outputs by switching an electrical connection state of the second conversion transistor, the number of parallel outputs being a number of the second conversion transistors that are connected in parallel to the first conversion transistor and convert the photocurrent into the voltage signal and output the voltage signal from the gate.
(2)

The light detection element according to (1), in which the connection switching section switches the number of parallel outputs according to information regarding a state of a subject or around the subject.
(3)

The light detection element according to (2), in which the connection switching section switches the number of parallel outputs according to illuminance of the subject or around the subject.
(4)

The light detection element according to (1), in which the connection switching section switches the number of parallel outputs according to the voltage signal.
(5)

The light detection element according to (1), further including
an event detection section that detects a change in the voltage signal as an event,
in which the connection switching section switches the number of parallel outputs according to a number of detected events.
(6)

The light detection element according to any one of (1) to (5),
in which each of the second conversion transistors is connected between a first node and a second node,
the first node includes a node between the photodiode and the first conversion transistor,
the second node includes a node between a first reference voltage node and the first conversion transistor, and
the connection switching section includes a first switching transistor connected between the first node and the second conversion transistor or between the second node and the second conversion transistor.
(7)

The light detection element according to any one of (1) to (5),
in which the connection switching section includes a voltage node capable of changing a voltage,
each of the second conversion transistors is connected between the voltage node and a first node, and
the first node includes a node between the photodiode and the first conversion transistor.
(8)

The light detection element according to any one of (1) to (5), in which the connection switching section includes a second switching transistor connected between a gate of each of the second conversion transistors and the output signal line.
(9)

The light detection element according to (8),
in which the connection switching section further includes a third switching transistor connected between a third node and a second reference voltage node, and
the third node includes a node between a gate of each of the second conversion transistors and the second switching transistor.
(10)

The light detection element according to (9), in which the connection switching section further includes an inverter connected between a gate of each of the second switching transistors and a gate of the third switching transistor.
(11)

The light detection element according to any one of (1) to (10), in which the first conversion transistor and each of the second conversion transistors are disposed adjacent to each other.
(12)

The light detection element according to any one of (1) to (11), in which each of the second conversion transistors and the connection switching section are provided in some pixels.
(13)

The light detection element according to any one of (1) to (12), in which each of the second conversion transistors and the connection switching section are provided in all pixels.

Aspects of the present disclosure are not limited to the above-described individual embodiments, but include various modifications that can be conceived by those skilled in the art, and the effects of the present disclosure are not limited to the above-described contents. That is, various additions, modifications, and partial deletions are possible without departing from the conceptual idea and spirit of the present disclosure derived from the matters defined in the claims and equivalents thereof.

### REFERENCE SIGNS LIST

10 Imaging system
11 Imaging lens
12 Recording section
13 Control section
20 Imaging device
21 Pixel array section
22 Drive section
23 Arbiter section
24 Column processing section
25 Signal processing section
27 Read area selection section
28 Signal generation section
30 Pixel
31 Light reception section
32 Pixel signal generation section
33 Address event detection section
331 Current-voltage conversion section
3312 P-type transistor
3313 N-type transistor
3315 Output signal line
3317 Connection switching section
AMP1 Conversion transistor
AMP2 Conversion transistor
INV Inverter
SW1 to SW3 Switching transistor
RC1 Response characteristics
RC2 Response characteristics
VDD Reference voltage node
VDD2 Voltage node
VR Reference voltage node

What is claimed is:

1. A light detection element comprising:
a photodiode that photoelectrically converts incident light to generate a photocurrent;
a first conversion transistor that converts the photocurrent into a voltage signal and outputs the voltage signal from a gate;
a current source transistor that supplies a predetermined constant current to an output signal line connected to the gate of the first conversion transistor;
a voltage supply transistor that supplies a constant voltage according to the predetermined constant current from the output signal line to a source of the first conversion transistor;
one or more second conversion transistors connected in parallel to the first conversion transistor and capable of converting the photocurrent into the voltage signal and outputting the voltage signal from a gate, and
a connection switching section that switches a number of parallel outputs by switching an electrical connection state of the second conversion transistor, the number of parallel outputs being a number of the second conversion transistors that are connected in parallel to the first conversion transistor and convert the photocurrent into the voltage signal and output the voltage signal from the gate.

2. The light detection element according to claim 1, wherein the connection switching section switches the number of parallel outputs according to information regarding a state of a subject or around the subject.

3. The light detection element according to claim 2, wherein the connection switching section switches the number of parallel outputs according to illuminance of the subject or around the subject.

4. The light detection element according to claim 1, wherein the connection switching section switches the number of parallel outputs according to the voltage signal.

5. The light detection element according to claim 1, further comprising an event detection section that detects a change in the voltage signal as an event,
wherein the connection switching section switches the number of parallel outputs according to a number of detected events.

6. The light detection element according to claim 1,
wherein each of the second conversion transistors is connected between a first node and a second node,
the first node includes a node between the photodiode and the first conversion transistor,
the second node includes a node between a first reference voltage node and the first conversion transistor, and
the connection switching section includes a first switching transistor connected between the first node and the second conversion transistor or between the second node and the second conversion transistor.

7. The light detection element according to claim 1,
wherein the connection switching section includes a voltage node capable of changing a voltage,
each of the second conversion transistors is connected between the voltage node and a first node, and
the first node includes a node between the photodiode and the first conversion transistor.

8. The light detection element according to claim 1, wherein the connection switching section includes a second switching transistor connected between a gate of each of the second conversion transistors and the output signal line.

9. The light detection element according to claim 8,
wherein the connection switching section further includes a third switching transistor connected between a third node and a second reference voltage node, and
the third node includes a node between a gate of each of the second conversion transistors and the second switching transistor.

10. The light detection element according to claim 9, wherein the connection switching section further includes an inverter connected between a gate of each of the second switching transistors and a gate of the third switching transistor.

11. The light detection element according to claim 1, wherein the first conversion transistor and each of the second conversion transistors are disposed adjacent to each other.

12. The light detection element according to claim 1, wherein each of the second conversion transistors and the connection switching section are provided in some pixels.

13. The light detection element according to claim 1, wherein each of the second conversion transistors and the connection switching section are provided in all pixels.
